(19) United States
(12) Patent Application Publication
(10) Pub. No.: US 2023/0200160 A1
(43) Pub. Date: Jun. 22, 2023

(54) DISPLAY DEVICE

(71) Applicant: LG Display Co., Ltd., Seoul (KR)

(72) Inventors: Chulyoung JANG, Daegu (KR); SangMo BYUN, Gimpo-si (KR); Hyun KIM, Gimpo-si (KR); Dayeon JEONG, Sejong-si (KR); Yooji HWANG, Seoul (KR)

(21) Appl. No.: 18/060,505

(22) Filed: Nov. 30, 2022

(30) Foreign Application Priority Data
Dec. 20, 2021 (KR) 10-2021-0182844

(51) Int. Cl. H01L 31/036

(52) U.S. Cl. CPC H01L 27/3276; H01L 51/5225; H01L 51/5209; H01L 51/5256; H01L 27/3246

(57) ABSTRACT

According to an aspect of the present disclosure, a display device includes a first substrate including an active area and a non-active area adjacent the active area; a plurality of light emitting diodes in the active area of the first substrate; a first electrode and a second electrode in the non-active area of the first substrate and spaced apart from each other; a plurality of structures between the first electrode and the second electrode and spaced apart from each other; and a connection layer on the plurality of structures and electrically connecting the first electrode and the second electrode.

### CROSS-REFERENCE TO RELATED APPLICATIONS

This application claims the priority of Korean Patent Application No. 10-2021-0182844 filed on Dec. 20, 2021, in the Korean Intellectual Property Office, the disclosure of which is incorporated herein by reference.

### BACKGROUND

### Technical Field

The present disclosure relates to a display device, and more particularly, to a display device which easily detects moisture permeation.

### Description of the Related Art

Currently, as it enters a full-fledged information era, a field of a display device which visually expresses electrical information signals has been rapidly developing and studies are continued to improve performances of various display devices such as a thin-thickness, a light weight, and low power consumption.

Among various display devices, a light emitting display device is a self-emitting display device so that a separate light source is not necessary, which is different from the liquid crystal display device. Therefore, the light emitting display device may be manufactured to have light weight and small thickness. Further, the light emitting display device is driven at a low voltage so that it is advantageous not only in terms of power consumption, but also in terms of color implementation, a response speed, a viewing angle, and a contrast ratio (CR). Therefore, it is expected to be utilized in various fields.

### BRIEF SUMMARY

A technical advantage to be achieved by the present disclosure is to provide a display device which easily detects moisture permeation.

Another technical advantage to be achieved by the present disclosure is to provide a display device which quantitatively determines a degree of permeation of moisture or oxygen.

Technical advantages of the present disclosure are not limited to the above-mentioned technical advantages, and other technical advantages, which are not mentioned above, can be clearly understood by those skilled in the art from the following descriptions.

According to an aspect of the present disclosure, a display device includes a first substrate including an active area and a non-active area adjacent the active area; a plurality of light emitting diodes in the active area of the first substrate; a first electrode and a second electrode in the non-active area of the first substrate and spaced apart from each other; a plurality of structures between the first electrode and the second electrode and spaced apart from each other; and a connection layer on the plurality of structures and electrically connecting the first electrode and the second electrode.

Other detailed matters of the embodiments are included in the detailed description and the drawings.

According to the present disclosure, a resistance of a connection layer in the display device is measured by a first electrode and a second electrode which protrude to the outside of the display device to determine whether moisture permeates.

According to the present disclosure, a degree of moisture permeation may be quantitatively determined by means of a resistance of the connection layer.

The effects according to the present disclosure are not limited to the contents exemplified above, and more various effects are included in the present specification.

### BRIEF DESCRIPTION OF THE SEVERAL VIEWS OF THE DRAWINGS

The above and other aspects, features and other advantages of the present disclosure will be more clearly understood from the following detailed description taken in conjunction with the accompanying drawings, in which:

FIG. 1 is a plan view of a display device according to an embodiment of the present disclosure;

FIG. 2 is a cross-sectional view taken along a line II-II′ of FIG. 1;

FIG. 3 is an enlarged plan view of a portion A of FIG. 1;

FIG. 4 is a cross-sectional view taken along a line IV-IV′ of FIG. 3;

FIGS. 5A to 5E sequentially illustrate a manufacturing process of a display device according to an embodiment of the present disclosure; and

FIG. 6 is a cross-sectional view of a display device according to another embodiment of the present disclosure.

### DETAILED DESCRIPTION

Advantages and characteristics of the present disclosure and a method of achieving the advantages and characteristics will be clear by referring to embodiments described below in detail together with the accompanying drawings. However, the present disclosure is not limited to the embodiments disclosed herein but will be implemented in various forms. The embodiments are provided by way of example only so that those skilled in the art can fully understand the disclosures of the present disclosure and the scope of the present disclosure.

The shapes, sizes, ratios, angles, numbers, and the like illustrated in the accompanying drawings for describing the embodiments of the present disclosure are merely examples, and the present disclosure is not limited thereto. Like reference numerals generally denote like elements throughout the specification. Further, in the following description of the present disclosure, a detailed explanation of known related technologies may be omitted to avoid unnecessarily obscuring the subject matter of the present disclosure. The terms such as “including,” “having,” and “consist of” used herein are generally intended to allow other components to be added unless the terms are used with the term “only”. Any references to singular may include plural unless expressly stated otherwise.

Components are interpreted to include an ordinary error range even if not expressly stated.

When the position relation between two parts is described using the terms such as “on,” “above,” “below,” and “next,” one or more parts may be positioned between the two parts unless the terms are used with the term “immediately” or “directly.”

When an element or layer is disposed “on” another element or layer, another layer or another element may be interposed directly on the other element or therebetween.

Although the terms “first,” “second,” and the like are used for describing various components, these components are not confined by these terms. These terms are merely used for distinguishing one component from the other components. Therefore, a first component to be mentioned below may be a second component in a technical concept of the present disclosure.

Like reference numerals generally denote like elements throughout the specification.

A size and a thickness of each component illustrated in the drawing are illustrated for convenience of description, and the present disclosure is not limited to the size and the thickness of the component illustrated.

The features of various embodiments of the present disclosure can be partially or entirely adhered to or combined with each other and can be interlocked and operated in technically various ways, and the embodiments can be carried out independently of or in association with each other.

Hereinafter, the present disclosure will be described in detail with reference to accompanying drawings.

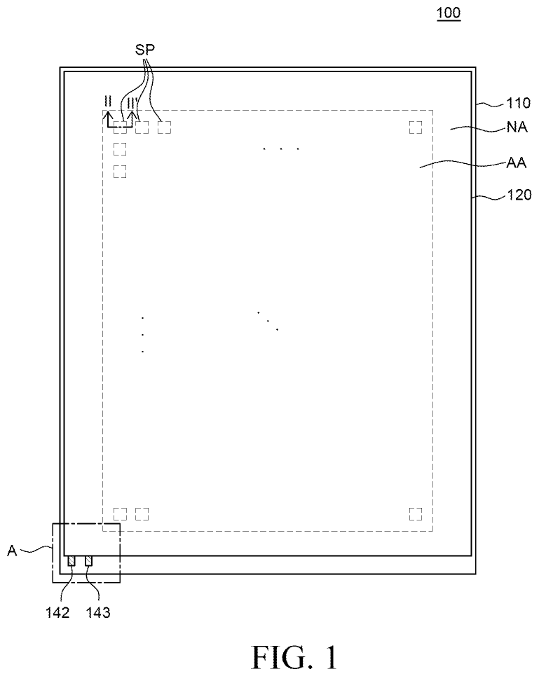

FIG. 1 is a plan view of a display device according to an embodiment of the present disclosure. In FIG. 1, for the convenience of description, among various components of a display device 100, only a first substrate 110, a second substrate 120, a first electrode 142, and a second electrode 143 are illustrated.

Referring to FIG. 1, the display device 100 according to an embodiment of the present disclosure includes the first substrate 110, the second substrate 120, the first electrode 142, and the second electrode 143.

The first substrate 110 is a substrate which supports and protects various components of the display device 100. The first substrate 110 includes an active area AA and a non-active area NA. The first substrate 110 may be formed of a glass or a plastic material having a flexibility. When the first substrate 110 is formed of a plastic material, for example, the first substrate may be formed of polyimide (PI), but is not limited thereto.

The active area AA is disposed in a center portion of the first substrate 110 and images may be displayed in the active area of the display device 100. In the active area AA, a display element and various driving elements for driving the display element may be disposed. For example, the display element may be configured by a light emitting diode 160 to be described below, including an anode 161, a light emitting layer 162, and a cathode 163. Further, various driving elements for driving the display element, such as a transistor 150, a capacitor, or wiring lines may be disposed in the active area AA.

A plurality of sub pixels SP may be included in the active area AA. The sub pixel SP is a minimum unit which configures a screen and each of a plurality of sub pixels SP may include a light emitting diode 160 and a driving circuit. A plurality of sub pixels SP may be positioned at an overlap area of a plurality of gate lines disposed in a first direction and a plurality of data lines disposed in a second direction which is different from the first direction. Here, the first direction may be a horizontal direction of FIG. 1 and the second direction may be a vertical direction of FIG. 1, but are not limited thereto. Each of a plurality of sub pixels SP may emit light having different wavelengths. For example, a plurality of sub pixels SP may include a red sub pixel, a green sub pixel, and a blue sub pixel. Further, a plurality of sub pixels SP may further include a white sub pixel.

The driving circuit of the sub pixel SP is a circuit for driving the light emitting diode 160. For example, the driving circuit may include a switching transistor, a driving transistor, and a capacitor. The driving circuit may be electrically connected to signal lines such as a gate line and a data line which are connected to a gate driver and a data driver disposed in the non-active area NA.

The non-active area NA is disposed in a circumferential area of the first substrate 110 and in the non-active area, images may not be displayed. The non-active area NA may be disposed so as to surround the active area AA, and is adjacent the active area AA, but is not limited thereto. Various components for driving a plurality of sub pixels SP disposed in the active area AA may be disposed in the non-active area NA. For example, a driving IC, a driving circuit, a signal line, and a flexible film which supply a signal for driving a plurality of sub pixels SP may be disposed. In this case, the driving IC may include a gate driver and a data driver.

The second substrate 120 is disposed to cover the first substrate 110. The second substrate 120 may be a substrate for protecting various components disposed on the first substrate 110. The second substrate 120 is bonded to the first substrate 110 by a sealing member 130 to be described below to seal components of the display device 100. The second substrate 120 may be formed of a glass or a plastic material having a flexibility, but is not limited thereto.

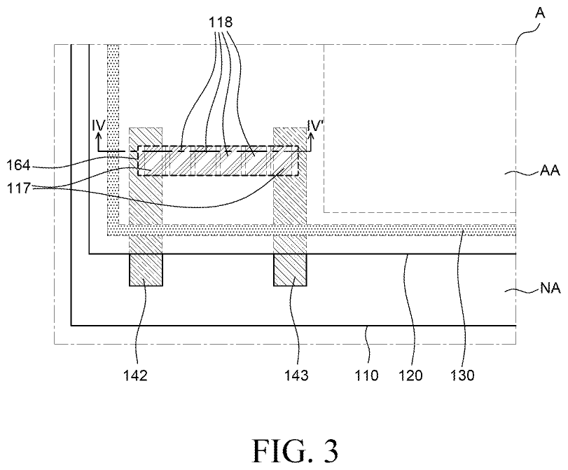

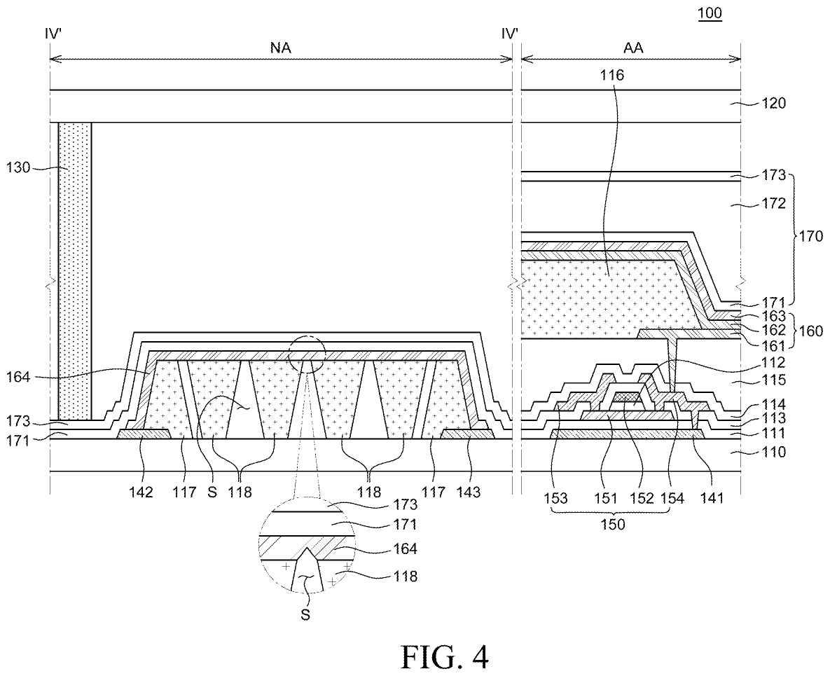

The first electrode 142 and the second electrode 143 are disposed in the non-active area NA of the first substrate 110. The first electrode 142 and the second electrode 143 may be disposed to protrude to the outside of the second substrate 120. The first electrode 142 and the second electrode 143 may be electrodes for detecting moisture permeation of the display device 100, which will be described in more detail with reference to FIGS. 3 and 4.

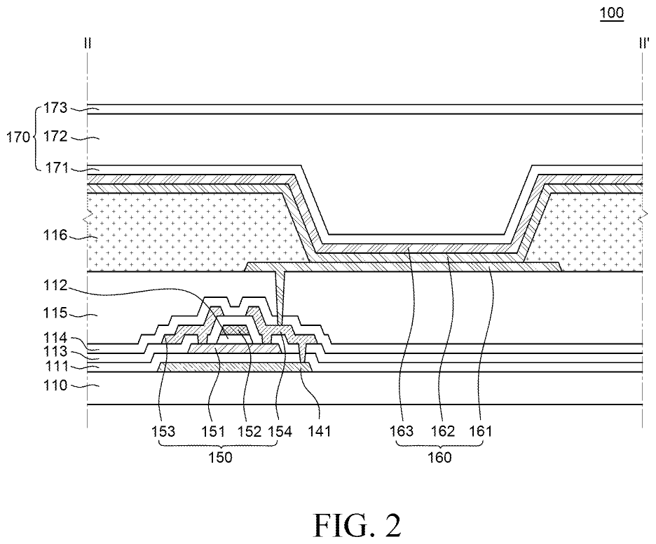

FIG. 2 is a cross-sectional view taken along a line II-II′ of FIG. 1. For the convenience of description, in FIG. 2, the second substrate 120 is omitted.

Referring to FIG. 2, a display device 100 includes a first substrate 110, a protective layer 141, a transistor 150, a light emitting diode 160, and an encapsulation unit or structure 170. The display device 100 may be implemented as a top emission type display device, but is not limited thereto.

The protective layer 141 is disposed on the first substrate 110. The protective layer 141 may be disposed so as to overlap the transistor 150. The protective layer 141 is formed of a metal material to be electrically connected to the source electrode 153 or the drain electrode 154 of the transistor 150, but is not limited thereto. For example, the protective layer 141 may be formed of molybdenum (Mo) and may be electrically connected to the drain electrode 154, but is not limited thereto. The protective layer 141 may be selectively formed only in an area beneficial to performance of the display device 100. For example, the protective layer 141 may be disposed so as to overlap a transistor 150 which serves as a driving transistor, but is not limited thereto. That is, the protective layer 141 may be disposed under a transistor other than the driving transistor.

The protective layer 141 may block a potential generated on a surface of the first substrate 110 and light coming in from the outside. Specifically, the protective layer 141 may overlap the active layer 151 of the transistor 150. Therefore, the protective layer 141 may suppress deterioration of a channel region of the active layer 151. Further, the protective layer 141 protects the transistor 150 from particles with charges generated from the first substrate 110 and may minimize or reduce the influence on the charges flowing in the channel of the transistor 150. Therefore, the shift phenomenon of a threshold voltage and a current drop phenomenon of the transistor 150 are improved and the reliability of the display device 100 may be improved.

The protective layer 141 is formed of a metal material so that the protective layer 141 and the active layer 151 may serve as elements which form a capacitance. At this time, when the protective layer 141 is electrically floated, a parasitic capacitance fluctuates and a shifted amount of the threshold voltage of the transistor may vary. This may cause a visual defect such as a luminance change. Therefore, the protective layer 141 is electrically connected to the source electrode 153 or the drain electrode 154 to maintain the parasitic capacitance constant. That is, the same voltage as the source electrode 153 or the drain electrode 154 may be applied to the protective layer 141.

A buffer layer 111 is disposed on the first substrate 110 and the protective layer 141. The buffer layer 111 may reduce permeation of moisture or impurities through the first substrate 110. Further, the buffer layer 111 may protect the transistor 140 from impurities such as alkali ions leaked from the first substrate 110. Furthermore, the buffer layer 111 may enhance an adhesiveness between layers formed above the buffer layer and the first substrate 110. The buffer layer 111 may be formed as a single layer of silicon nitride (SiNx) or silicon oxide (SiOx), or as a multiple layer of silicon nitride (SiNx) or silicon oxide (SiOx), but is not limited thereto. The buffer layer 111 is an optional component and may be omitted based on a type and a material of the first substrate 110, or a structure and a type of the transistor 150. In the meantime, in some cases, the buffer layer 111 may also be disposed between the first substrate 110 and the protective layer 141.

The transistor 150 is disposed on the buffer layer 111. The transistor 150 may be used as a driving element which drives the light emitting diode 160 of the active area AA. The transistor 150 includes an active layer 151, a gate electrode 152, a source electrode 153, and a drain electrode 154. The transistor 150 illustrated in FIG. 2 is a driving transistor and is a top gate type thin film transistor in which the gate electrode 152 is disposed on the active layer 151. However, it is not limited thereto and the transistor 150 may be implemented as a bottom gate type transistor.

In FIG. 2, only the driving transistor 150, among various transistors included in the display device 100, is illustrated, but the other transistors such as a switching transistor may also be disposed.

The active layer 151 is disposed on the buffer layer 111. The active layer 151 is an area in which a channel is formed when the transistor 150 is driven. The active layer 151 may be formed of an oxide semiconductor, amorphous silicon (a-Si), polycrystalline silicon (poly-Si), an organic semiconductor, or the like.

A gate insulating layer 112 is disposed on the active layer 151. The gate insulating layer 112 is a layer for electrically insulating the gate electrode 151 from the active layer 152 and may be formed of an insulating material. The gate insulating layer 112 may be patterned on the active layer 151, as illustrated in FIG. 2, to have the same width as the gate electrode 152 or formed on the entire first substrate 110, but is not limited thereto. The gate insulating layer 112 may be formed as a single layer of silicon nitride (SiNx) or silicon oxide (SiOx) which is an inorganic material, or as a multiple layer of silicon nitride (SiNx) or silicon oxide (SiOx), but it is not limited thereto.

The gate electrode 152 is disposed on the gate insulating layer 112. The gate electrode 152 is disposed on the gate insulating layer 112 so as to overlap a channel region of the active layer 151. The gate electrode 152 may be any one of various metal materials, for example, molybdenum (Mo), aluminum (Al), chrome (Cr), gold (Au), titanium (Ti), nickel (Ni), neodymium (Nd), and copper (Cu), or an alloy of two or more of them, or a multiple layer thereof, but it is not limited thereto.

An interlayer insulating layer 113 is disposed on the gate electrode 152. The interlayer insulating layer 113 may be formed as a single layer of silicon nitride (SiNx) or silicon oxide (SiOx) which is an inorganic material, or as a multiple layer of silicon nitride (SiNx) or silicon oxide (SiOx), but it is not limited thereto. In the interlayer insulating layer 113, contact holes through which the source electrode 153 and the drain electrode 154 are in contact with the source region and the drain region of the active layer 151, respectively, are formed.

The source electrode 153 and the drain electrode 154 are disposed on the interlayer insulating layer 113. The source electrode 153 and the drain electrode 154 are disposed on the same layer to be spaced apart from each other. The source electrode 153 and the drain electrode 154 are electrically connected to the active layer 151 through the contact holes of the interlayer insulating layer 113. The source electrode 153 and the drain electrode 154 may be any one of various metal materials such as molybdenum (Mo), aluminum (Al), chrome (Cr), gold (Au), titanium (Ti), nickel (Ni), neodymium (Nd), and copper (Cu), or an alloy of two or more of them, or a multiple layer thereof, but it is not limited thereto.

A passivation layer 114 is disposed on the transistor 150. The passivation layer 114 may be disposed so as to cover the source electrode 153, the drain electrode 154, and the interlayer insulating layer 113. The passivation layer 114 may be formed as a single layer of silicon nitride (SiNx) or silicon oxide (SiOx), or as a multiple layer of silicon nitride (SiNx) or silicon oxide (SiOx), but it is not limited thereto. A planarization layer 115 is disposed on the passivation layer 114. The planarization layer 115 is an insulating layer for protecting the transistor 150 and planarizing an upper portion of the transistor 150. A contact hole which exposes the drain electrode 154 of the transistor 150 is formed on the planarization layer 115. However, it is not limited thereto and a contact hole which exposes the source electrode 153 may also be formed on the planarization layer 115. The planarization layer 115 may be formed of one of acrylic resin, epoxy resin, phenol resin, polyamide-based resin, polyimide-based resin, unsaturated polyester-based resin, polyphenylene-based resin, polyphenylene sulfide-based resin, benzocyclobutene, and photoresist, but is not limited thereto.

The light emitting diode 160 is disposed on the planarization layer 115. The light emitting diode 160 includes an anode 161, a light emitting layer 162, and a cathode 163.

The anode 161 is disposed on the planarization layer 115. The anode 161 is disposed so as to correspond to each of a plurality of sub pixels SP. The anode 161 may be electrically connected to the drain electrode 154 of the transistor 150. However, the anode 161 may be configured to be electrically connected to the source electrode 153 of the transistor 150 depending on a type of the transistor 150, a design manner of the driving circuit, or the like.

The anode 161 may be formed of a conductive material having a high work function to supply holes to the light emitting layer 162. The anode 161 may be formed to have a multi-layered structure including a transparent conductive film and an opaque conductive film having high reflection efficiency. The transparent conductive film may be formed of a material having a relatively high work function, such as indium tin oxide (ITO) or indium zinc oxide (IZO). The opaque conductive film may be formed to have a single layer or a multi-layered structure including Al, Ag, Cu, Pb, Mo, Ti, or an alloy thereof. However, the material of the anode 161 is not limited thereto.

A bank 116 is disposed on the planarization layer 115 and the anode 161. The bank 116 may be formed on the planarization layer 115 so as to cover an edge of the anode 161. The bank 116 is an insulating layer disposed between a plurality of sub pixels SP to isolate a plurality of sub pixels SP from each other. The bank 116 may be an organic insulating material. For example, the bank 116 may be formed of one of acrylic resin, epoxy resin, phenol resin, polyamide-based resin, polyimide-based resin, unsaturated polyester-based resin, polyphenylene-based resin, polyphenylene sulfide-based resin, benzocyclobutene, and photoresist, but is not limited thereto.

The light emitting layer 162 is disposed on the anode 161 and the bank 116. The light emitting layer 162 may be an organic layer which emits light having a specific color. For example, the light emitting layer 162 may be one of a red light emitting layer, a green light emitting layer, a blue light emitting layer, and a white light emitting layer. When the light emitting layer 162 is configured by the white light emitting layer, a color filter may be further disposed above the light emitting diode 160. The light emitting layer 162 may further include various layers such as a hole transport layer, a hole injection layer, a hole blocking layer, an electron injection layer, an electron blocking layer, or an electron transport layer.

The cathode 163 is disposed on the light emitting layer 162. The cathode 163 may be formed as a single layer over the entire surface of the first substrate 110. That is, the cathode 163 may be a common layer which is commonly formed for a plurality of sub pixels SP. The cathode 163 supplies electrons to the light emitting layer 162 so that the cathode may be formed of a conductive material having a low work function. For example, the cathode 163 may be formed of a transparent conductive material such as indium tin oxide (ITO) or indium zinc oxide (IZO), a metal alloy such as MgAg, or a ytterbium (Yb) alloy. Alternatively, the cathode 163 may further include a metal doping layer, but is not limited thereto.

The encapsulation unit or structure 170 is disposed on the light emitting diode 160. For example, the encapsulation unit 170 is disposed on the cathode 163 so as to cover the light emitting diode 160. The encapsulation unit 170 protects the light emitting diode 160 from moisture or oxygen permeating into the display device 100 from the outside. The encapsulation unit 170 may have a structure in which an inorganic layer and an organic layer are alternately laminated. The encapsulation unit 170 includes a first encapsulation layer 171, a foreign material cover layer 172, and a second encapsulation layer 173.

The first encapsulation layer 171 is disposed on the cathode 163 to suppress the permeation of the moisture or oxygen. The first encapsulation layer 171 may be formed of an inorganic material such as silicon nitride (SiNx), silicon oxynitride (SiNxOy), silicon oxide (SiOx), or aluminum oxide (AlyOz), but is not limited thereto.

The foreign material cover layer 172 is disposed on the first encapsulation layer 171 to planarize the surface. Further, the foreign material cover layer 172 may cover foreign materials or particles which may be generated during a manufacturing process. The foreign material cover layer 172 may be formed of an organic material, such as silicon oxy carbon (SiOxCz), or acrylic or epoxy resin, but is not limited thereto.

The second encapsulation layer 173 is disposed on the foreign material cover layer 172 and may suppress the permeation of the moisture or oxygen, like the first encapsulation layer 171. The second encapsulation layer 173 may be formed of an inorganic material such as silicon nitride (SiNx), silicon oxynitride (SiNxOy), silicon oxide (SiOx), or aluminum oxide (AlyOz), but is not limited thereto. The second encapsulation layer 173 may be formed of the same material as the first encapsulation layer 171 or formed of a different material.

FIG. 3 is an enlarged plan view of a portion A of FIG. 1. FIG. 4 is a cross-sectional view taken along a line IV-IV′ of FIG. 3.

Referring to FIGS. 3 and 4, the display device 100 includes a first electrode 142, a second electrode 143, a plurality of structures 117 and 118, and a connection layer 164 disposed in the non-active area NA.

The first electrode 142 and the second electrode 143 are disposed in the non-active area NA of the first substrate 110. The first electrode 142 and the second electrode 143 may be disposed so as to be spaced apart from each other. As illustrated in FIG. 3, the first electrode 142 and the second electrode 143 may be formed to protrude to the outside of the second substrate 120 and the sealing member 130. That is, the first electrode 142 and the second electrode 143 may extend from the inside to the outside of the display device 100. Accordingly, after completing the manufacturing process of the display device 100, it is possible to detect moisture permeation of the display device 100 by means of the first electrode 142 and the second electrode 143. The first electrode 142 and the second electrode 143 may be formed by the same process as the protective layer 141. That is, the first electrode 142 and the second electrode 143 may be formed of the same material on the same layer as the protective layer 141. For example, the first electrode 142 and the second electrode 143 may be formed of molybdenum (Mo), but are not limited thereto.

A plurality of structures 117 and 118 may be disposed between the first electrode 142 and the second electrode 143 so as to be spaced apart from each other. That is, a plurality of structures 117 and 118 may be disposed so as to have a space S therebetween. A plurality of structures 117 and 118 includes a first structure 117 and a second structure 118.

The first structure 117 is disposed so as to overlap each of the first electrode 142 and the second electrode 143. That is, the first structure 117 may be provided as a pair. The first structure 117 is disposed so as to cover parts of each of the first electrode 142 and the second electrode 143. A cross-section of the first structure 117 may be formed to have a trapezoidal shape (e.g., to have tapered sidewalls). The first structure 117 may be formed of the same material by the same process as the bank 116. For example, the first structure 117 may be formed of one of acrylic resin, epoxy resin, phenol resin, polyamide-based resin, polyimide-based resin, unsaturated polyester-based resin, polyphenylene-based resin, polyphenylene sulfide-based resin, benzocyclobutene, and photoresist, but is not limited thereto.

The second structure 118 is disposed between one pair of the first structures 117. A plurality of second structures 118 is provided to be spaced apart from each other. A cross-section of the second structure 118 may be formed to have an inverted trapezoidal shape. A plurality of second structures 118 may be formed of the same material as the first structure 117 and the bank 116, but is not limited thereto. That is, a plurality of second structures 118 may be formed of a different material from the first structure 117 and the bank 116. A plurality of second structures 118 may be formed of one of acrylic resin, epoxy resin, phenol resin, polyamide-based resin, polyimide-based resin, unsaturated polyester-based resin, polyphenylene-based resin, polyphenylene sulfide-based resin, benzocyclobutene, and photoresist, but is not limited thereto.

The connection layer 164 is disposed on a plurality of structures 117 and 118. The connection layer 164 may electrically connect the first electrode 142 and the second electrode 143. The connection layer 164 may be formed of the same material by the same process as the cathode 163. For example, the connection layer 164 may be formed of a transparent conductive material such as indium tin oxide (ITO) or indium zinc oxide (IZO), a metal alloy such as MgAg, or a ytterbium (Yb) alloy. Alternatively, the connection layer 164 may further include a metal doping layer, but is not limited thereto.

Parts of the connection layer 164 corresponding to each of a plurality of structures 117 and 118 may be continuously formed. That is, the connection layer 164 may be integrally formed on a plurality of structures 117 and 118 as a single layer. At this time, a thickness of the portion of the connection layer 164 which corresponds to the space S between a plurality of structures 117 and 118 may be formed to be smaller than a thickness of a portion of the connection layer 164 which is in direct contact with a plurality of structures 117 and 118. Therefore, when moisture permeation occurs in the display device 100, a thin portion of the connection layer 164 may react with moisture or oxygen more sensitively than the other portion. Accordingly, whether moisture permeates into the display device 100 may be detected by measuring the resistance change of the connection layer 164.

To be more specific, the connection layer 164 may be formed of a material having an excellent step coverage, which is the same as the cathode 163. Therefore, when the connection layer 164 is deposited on a plurality of structures 117 and 118 which is spaced apart from each other, the materials of the connection layer 164 may grow not only on upper surfaces of a plurality of structures 117 and 118 but also in a lateral direction. Accordingly, the materials of the connection layer 164 deposited on each of the upper surfaces of a plurality of structures 117 and 118 may be connected to each other by the growth in the lateral direction. That is, the connection layer 164 may be formed on the space S in which a plurality of structures 117 and 118 is not present. However, the connection layer 164 in the area corresponding to the space S is not directly deposited on the upper surfaces of a plurality of structures 117 and 118 so that the thickness thereof may be relatively thinner than the other area. Specifically, the thin area of the connection layer 164 may be exposed by the space S. Accordingly, the thin area of the connection layer 164 may easily react with the moisture or oxygen.

A distance between a plurality of structures 117 and 118 may be 0.05 to 0.15 times a height of a plurality of structures 117 and 118. At this time, the distance between a plurality of structures 117 and 118 may refer to a shortest distance of the space S between a plurality of structures 117 and 118. In other words, it means a distance between upper surfaces of a plurality of structures 117 and 118 which is adjacent to each other. When the distance between a plurality of structures 117 and 118 is smaller than 0.05 times a height of a plurality of structures 117 and 118, a sufficient process margin for forming a plurality of structures 117 and 118 may not be ensured. When the distance between a plurality of structures 117 and 118 is larger than 0.15 times the height of a plurality of structures 117 and 118, the connection layer 164 which is deposited on a plurality of structures 117 and 118 may be broken.

A step coverage of a deposition material of the connection layer 164 may be 30% or higher. When the step coverage of the deposition material of the connection layer 164 is lower than 30%, the connection layer 164 may be broken in the area corresponding to the space S.

The thickness of the connection layer 164 may be 0.1 to 0.2 times the height of a plurality of structures 117 and 118. At this time, the thickness of the connection layer 164 may mean a thickness of a thickest area of the connection layer 164. When the thickness of the connection layer 164 is smaller than 0.1 times the height of a plurality of structures 117 and 118, the connection layer 164 which is deposited on a plurality of structures 117 and 118 may be broken. That is, the connection layer 164 grows to be thin in the thickness direction so that the growth in the lateral direction may not be sufficiently performed. When the thickness of the connection layer 164 is larger than 0.2 times the height of a plurality of structures 117 and 118, the accuracy of detecting the moisture permeation may be lowered. That is, even though the connection layer 164 reacts with the moisture or oxygen, the resistance change is insignificant so that the detection accuracy may be lowered.

In the meantime, in FIGS. 3 and 4, it is illustrated that four second structures 118 are configured, but it is not limited thereto. Further, in FIGS. 3 and 4, it is illustrated that distances between a plurality of structures 117 and 118 are constant (i.e., the same as each other), but it is not limited thereto. That is, the distance between a plurality of structures 117 and 118 may be formed to be larger or smaller in a specific area. For example, the distance between a plurality of structures 117 and 118 is the largest at the center and may become narrower toward the outer edge.

In the non-active area NA, a first encapsulation layer 171 and a second encapsulation layer 173 are disposed on the connection layer 164, the first electrode 142, the second electrode 143, and the first substrate 110. The first encapsulation layer 171 and the second encapsulation layer 173 may suppress the permeation of the moisture and oxygen into the connection layer 164, the first electrode 142, the second electrode 143, and the first substrate 110. Further, even though in FIG. 4, it is illustrated that the foreign material cover layer 172 is disposed only in the active area AA, the foreign material cover layer 172 may also be disposed in a part of the non-active area NA.

The first substrate 110 and the second substrate 120 may be bonded by the sealing member 130. The sealing member 130 may block a space between the first substrate 110 and the second substrate 120 from the outside. The sealing member 130 may be disposed on the first encapsulation layer 171 and the second encapsulation layer 173, but is not limited thereto. That is, the sealing member 130 may be disposed so as to be in direct contact with the first substrate 110 and the second substrate 120 at the outside of the first encapsulation layer 171 and the second encapsulation layer 173.

Generally, when moisture permeation occurs in the display device, internal devices such as a transistor or a light emitting diode are damaged. In order to detect the moisture permeation, after exposing the display device to a high temperature and high humidity environment for a long time, the presence or absence of the defects was determined by a lighting inspection. However, this method has disadvantages in that a long time is consumed and the quantitative evaluation is not easy. Further, there may be various causes for the defects, in addition to the moisture permeation, so that there is a limitation in analysis of a cause of the defects.

The display device 100 according to an embodiment includes the first electrode 142 and the second electrode 143 to easily detect moisture permeation. Specifically, the first electrode 142 and the second electrode 143 may protrude from the inside of the display device sealed by the first substrate 110, the second substrate 120, and the sealing member 130 to the outside of the second substrate 120 and the sealing member 130. Further, the first electrode 142 and the second electrode 143 may be electrically connected by the connection layer 164. At this time, the connection layer 164 may be disposed in the display device 100. Accordingly, a resistance change of the connection layer 164 disposed in the display device 100 may be measured by means of the first electrode 142 and the second electrode 143 which protrude to the outside of the display device 100. By doing this, it may be determined whether moisture permeates into the display device 100.

Specifically, the connection layer 164 may be deposited on a plurality of structures 117 and 118 which is spaced apart from each other. Here, there may be a space S between a plurality of structures 117 and 118. Therefore, a portion of the connection layer 164 is in direct contact with a plurality of structures 117 and 118, and the remaining portion is not in contact with a plurality of structures 117 and 118 but may be exposed through the space S. Accordingly, when the moisture or oxygen permeates into the display device 100, the connection layer 164 may easily react with the moisture or the oxygen by means of the exposed area.

An area of the connection layer 164 corresponding to the space S may have a thickness smaller than the area corresponding to a plurality of structures 117 and 118. Specifically, the connection layer 164 may be formed of a material having an excellent step coverage. Therefore, when the connection layer 164 is deposited, some of a deposition material of the connection layer 164 may grow not only in a thickness direction from an upper surface of a plurality of structures 117 and 118, but also in a lateral direction. That is, some of the deposition material of the connection layer 164 may grow to cover the space S with a relatively small thickness. Specifically, the thin portion of the connection layer 164 may be an area exposed by the space S. Accordingly, the small thickness may cause the connection layer 164 to more sensitively react with the moisture or oxygen. As a result, the moisture permeation of the display device 100 may be more accurately detected.

The display device 100 according to an embodiment of the present disclosure detects whether a moisture permeation occurs by measuring the resistance change of the connection layer 164 to quantitatively determine a degree of moisture permeation. Specifically, a degree of corrosion of the surface of the connection layer 164 may vary depending on the degree of permeation of the moisture or oxygen into the display device 100. When a large amount of moisture or oxygen permeates so that the connection layer 164 is strongly corroded, the resistance change may be relatively large. In contrast, when an amount of permeating moisture or oxygen is small so that the degree of corrosion of the connection layer 164 is small, the resistance may be slightly increased. Therefore, the degree of moisture permeation is quantitatively determined by means of the resistance change of the connection layer 164 and the reliability of the display device 100 may be evaluated.

Further, the display device 100 according to an embodiment of the present disclosure may easily determine the defect due to the moisture permeation. That is, the resistance change of the connection layer 164 may be generated by the reaction between the connection layer 164 and the moisture or oxygen. Accordingly, among various causes of defects which may be generated in the display device 100, the moisture permeation defect may be more accurately determined.

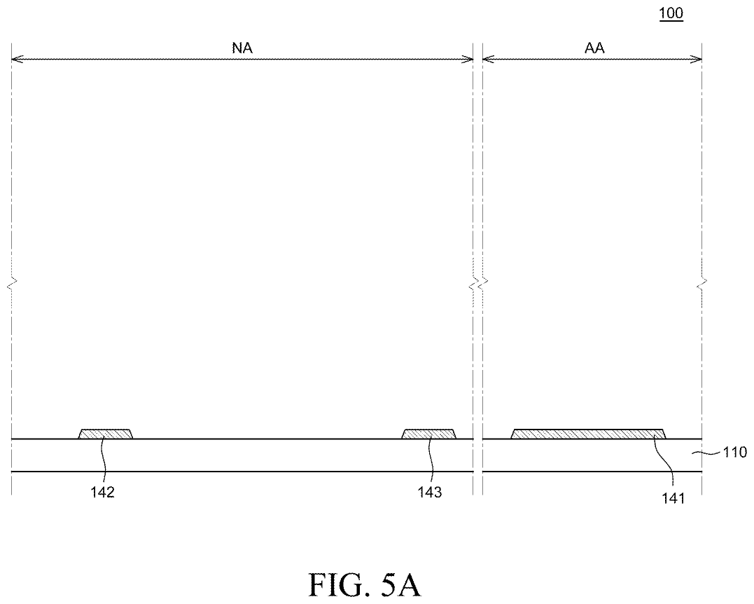

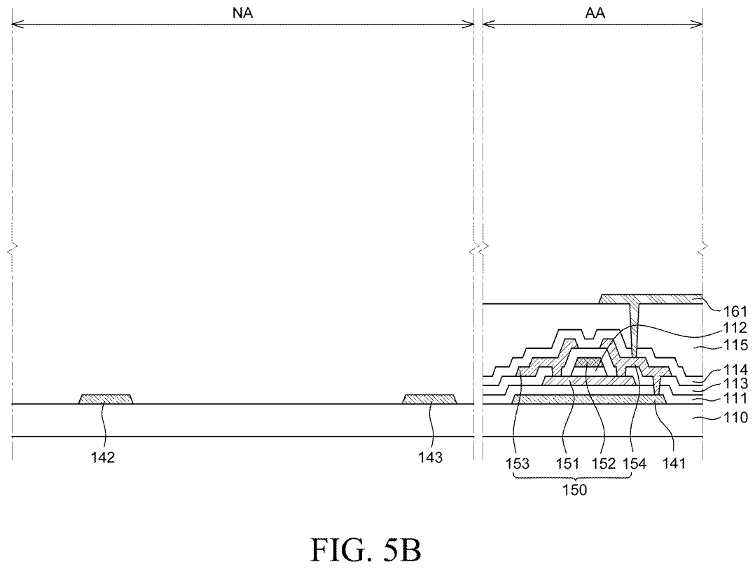

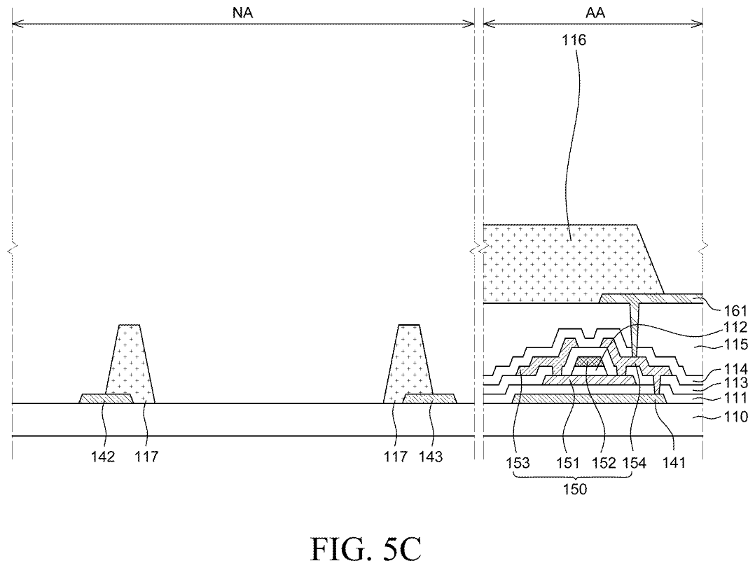

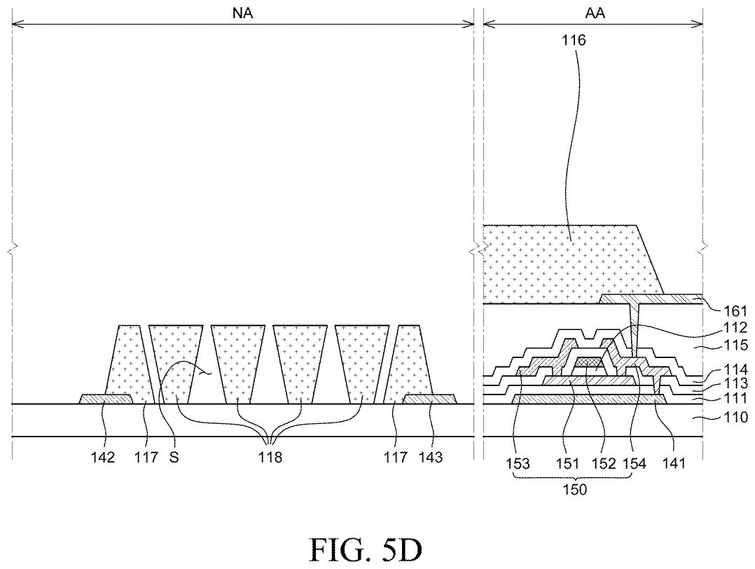

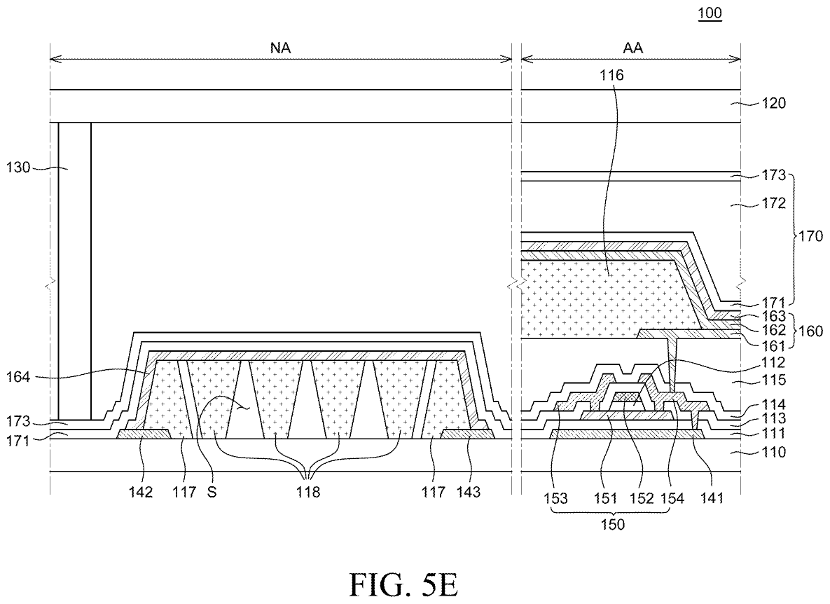

FIGS. 5A to 5E sequentially illustrate a manufacturing process of a display device according to an embodiment of the present disclosure.

Referring to FIG. 5A, the protective layer 141, the first electrode 142, and the second electrode 143 are formed on the first substrate 110. At this time, the protective layer 141 may be disposed in the active area AA and the first electrode 142 and the second electrode 143 may be disposed in the non-active area NA. The protective layer 141, the first electrode 142, and the second electrode 143 may be formed of the same material by the same process.

Referring to FIG. 5B, in the active area AA, the buffer layer 111, the active layer 151, the gate insulating layer 112, the gate electrode 152, the interlayer insulating layer 113, the source electrode 153, the drain electrode 154, the passivation layer 114, the planarization layer 115, and the anode 161 are sequentially formed.

Referring to FIG. 5C, the bank 116 and one pair of the first structures 117 are formed. At this time, the bank 116 may be disposed on the planarization layer 115 and the anode 161 in the active area AA. Each one pair of the first structures 117 may be disposed in the non-active area NA to cover a part of the first electrode 142 and the second electrode 143. The bank 116 and one pair of the first structures 117 may be formed of the same material by the same process. At this time, the bank 116 and one pair of the first structures 117 may be formed to have a trapezoidal cross-section using a positive photo resist.

Referring to FIG. 5D, a plurality of second structures 118 is formed between one pair of first structures 117. A plurality of second structures 118 may be formed in the non-active area NA to be spaced apart from each other. A plurality of second structures 118 may be formed of the same material as one pair of the first structures 117 and the bank 116, but is not limited thereto. A plurality of second structures 118 may be formed to have an inverted trapezoidal cross-section using a negative photo resist.

In the meantime, in FIG. 5D, it is illustrated that a plurality of second structures 118 is shown as four, but it is not limited thereto. Further, the distances between a plurality of second structures 118 may be equal to each other or different from each other, depending on the design.

Referring to FIG. 5E, the light emitting layer 162 and the cathode 163 are formed in the active area AA and then the connection layer 164 is formed in the non-active area NA. At this time, the cathode 163 and the connection layer 164 may be simultaneously formed after forming the light emitting layer 162. That is, the cathode 163 and the connection layer 164 may be formed of the same material by the same process. Specifically, the connection layer 164 may be formed as a single layer to cover the space S on a plurality of second structures 118 which is spaced apart from each other. That is, a deposition material of the cathode 163 and the connection layer 164 has an excellent step coverage to extend from upper surfaces of a plurality of second structures 118 so as to cover the space S.

In the meantime, when a plurality of second structures is spaced apart from each other with a trapezoidal cross section, the space between the upper surfaces of a plurality of second structures relatively increases. In this case, even though the connection layer is formed of a material having an excellent step coverage, the connection layers disposed on a plurality of second structures may be disconnected without being connected to each other. Accordingly, the cross-section of a plurality of second structures 118 may be preferably formed to have an inverted trapezoidal shape.

After forming the cathode 163 and the connection layer 164, the first encapsulation layer 171, the foreign material cover layer 172, and the second encapsulation layer 173 are formed. Further, the first substrate 110 and the second substrate 120 may be bonded by the sealing member 130.

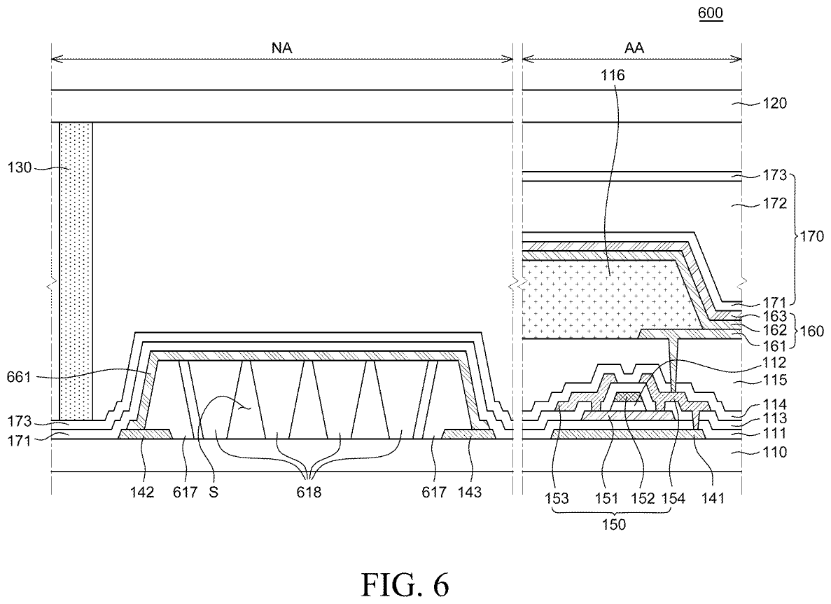

FIG. 6 is a cross-sectional view of a display device according to another embodiment of the present disclosure. The display device 600 of FIG. 6 is substantially the same as the display device 100 of FIGS. 1 to 4 except for a plurality of structures 617 and 618 and a connection layer 661 so that a redundant description will be omitted.

Referring to FIG. 6, in the non-active area NA of the first substrate 110, the first electrode 142, the second electrode 143, a plurality of structures 617 and 618, and the connection layer 661 are disposed.

A plurality of structures 617 and 618 may be disposed between the first electrode 142 and the second electrode 143 so as to be spaced apart from each other. That is, a plurality of structures 617 and 618 may be disposed so as to have a space S therebetween.

The first structure 617 is disposed so as to overlap each of the first electrode 142 and the second electrode 143. That is, the first structure 617 may be provided as a pair. The first structure 617 may be disposed so as to cover parts of each of the first electrode 142 and the second electrode 143. A cross-section of the first structure 617 may be formed to have a trapezoidal shape. The first structure 617 may be formed of the same material by the same process as the planarization layer 115. For example, the first structure 617 may be formed of one of acrylic resin, epoxy resin, phenol resin, polyamide-based resin, polyimide-based resin, unsaturated polyester-based resin, polyphenylene-based resin, polyphenylene sulfide-based resin, benzocyclobutene, and photoresist, but is not limited thereto.

The second structure 618 is disposed between the pair of the first structures 617. A plurality of second structures 618 is provided to be spaced apart from each other. A cross-section of the second structure 618 may be formed to have an inverted trapezoidal shape. A plurality of second structures 618 may be formed of the same material as the first structure 617 and the planarization layer 115, but is not limited thereto. That is, a plurality of second structures 618 may be formed of a different material from the first structure 617 and the planarization layer 115. A plurality of second structures 618 may be formed of one of acrylic resin, epoxy resin, phenol resin, polyamide-based resin, polyimide-based resin, unsaturated polyester-based resin, polyphenylene-based resin, polyphenylene sulfide-based resin, benzocyclobutene, and photoresist, but is not limited thereto.

The connection layer 661 is disposed on a plurality of structures 617 and 618. The connection layer 661 may electrically connect the first electrode 142 and the second electrode 143. The connection layer 661 may be formed of the same material by the same process as the anode 161. For example, the connection layer 661 may be formed of a single or a multi-layered structure including a transparent conductive material such as indium tin oxide (ITO) or indium zinc oxide (IZO), Al, Ag, Cu, Pb, Mo, Ti, or an alloy thereof, but is not limited thereto.

Parts of the connection layer 661 corresponding to each of a plurality of structures 617 and 618 may be continuously formed. That is, the connection layer 661 may be integrally formed on a plurality of structures 617 and 618 as a single layer. At this time, a thickness of the portion of the connection layer 661 which corresponds to the space S between a plurality of structures 617 and 618 may be formed to be smaller than a thickness of a portion of the connection layer 661 which is in direct contact with a plurality of structures 617 and 618. Therefore, when moisture permeation occurs in the display device 600, a thin portion of the connection layer 661 may react with moisture or oxygen more sensitively than the other portion. Accordingly, whether moisture permeation defect of the display device 600 may be detected by measuring the resistance change of the connection layer 661.

A distance between a plurality of structures 617 and 618 may be 0.05 to 0.15 times a height of a plurality of structures 617 and 618. The thickness of the connection layer 661 may be 0.1 to 0.2 times the height of a plurality of structures 617 and 618. A step coverage of a deposition material of the connection layer 661 may be 30% or larger.

In the meantime, in FIG. 6, it is illustrated that four second structures 618 are configured, but it is not limited thereto. Further, in FIG. 6, it is illustrated that distances between a plurality of structures 617 and 618 are constant, but it is not limited thereto. That is, the distance between a plurality of structures 617 and 618 may be formed to be larger or smaller in a specific area. For example, the distance between a plurality of structures 617 and 618 is the largest at the center and becomes narrower toward the outer edge.

The embodiments of the present disclosure can also be described as follows:

According to an aspect of the present disclosure, a display device includes a first substrate including an active area and a non-active area adjacent the active area; a plurality of light emitting diodes in the active area of the first substrate; a first electrode and a second electrode in the non-active area of the first substrate and spaced apart from each other; a plurality of structures between the first electrode and the second electrode and spaced apart from each other; and a connection layer on the plurality of structures and electrically connecting the first electrode and the second electrode.

The plurality of structures may include one pair of first structures overlapping the first electrode and the second electrode, respectively; and a plurality of second structures between the one pair of first structures and spaced apart from each other.

A cross section of the one pair of first structures may be configured to have a trapezoidal structure and a cross section of the plurality of second structures may be configured to have an inverted trapezoidal structure.

Portions of the connection layer corresponding to each of the plurality of structures may be continuously configured.

A thickness of a portion of the connection layer corresponding to a space between the plurality of structures may be smaller than a thickness of a portion of the connection layer which is in contact with the plurality of structures.

The display device may further include a transistor in the active area and connected to the plurality of light emitting diodes; and a protective layer overlapping the transistor under the transistor. The first electrode, the second electrode, and the protective layer may be configured by the same material.

The plurality of light emitting diodes may include an anode, a light emitting layer, and a cathode. A bank covering a part of the anode may be disposed under the light emitting layer. At least one of the plurality of structures and the bank may be configured by the same material. The connection layer and the cathode may be configured by the same material.

The display device may further include a transistor in the active area and connected to the plurality of light emitting diodes; a planarization layer covering the transistor; and anodes of the plurality of light emitting diodes disposed on the planarization layer. At least one of the plurality of structures and the planarization layer may be configured by the same material. The connection layer and the anodes may be configured by the same material.

The display device may further include a second substrate covering the first substrate; and a sealing member bonding the first substrate and the second substrate. The first electrode and the second electrode may protrude from an area overlapping the second substrate to the outside of the second substrate and the sealing member.

The connection layer may be disposed inside the sealing member.

Whether moisture permeation occurs may be detected by a resistance change of the connection layer measured by the first electrode and the second electrode.

Although the embodiments of the present disclosure have been described in detail with reference to the accompanying drawings, the present disclosure is not limited thereto and may be embodied in many different forms without departing from the technical concept of the present disclosure. Therefore, the embodiments of the present disclosure are provided for illustrative purposes only but not intended to limit the technical concept of the present disclosure. The scope of the technical concept of the present disclosure is not limited thereto. Therefore, it should be understood that the above-described embodiments are illustrative in all aspects and do not limit the present disclosure. The protective scope of the present disclosure should be construed based on the following claims, and all the technical concepts in the equivalent scope thereof should be construed as falling within the scope of the present disclosure.

The various embodiments described above can be combined to provide further embodiments. All of the U.S. patents, U.S. patent application publications, U.S. patent applications, foreign patents, foreign patent applications and non-patent publications referred to in this specification and/or listed in the Application Data Sheet are incorporated herein by reference, in their entirety. Aspects of the embodiments can be modified, if necessary to employ concepts of the various patents, applications and publications to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A display device, comprising:
a first substrate including an active area and a non-active area adjacent the active area;
a plurality of light emitting diodes in the active area of the first substrate;
a first electrode and a second electrode in the non-active area of the first substrate and spaced apart from each other;
a plurality of structures disposed on the first substrate and between the first electrode and the second electrode, a space being between each of the plurality of structures;
a connection layer on the plurality of structures and electrically connecting the first electrode and the second electrode,
wherein a portion of a lower surface of the connection layer is exposed to the space between the plurality of structures,
wherein the first electrode and the second electrode protrude to outside of the display device.

2. The display device according to claim 1, wherein the plurality of structures includes:
one pair of first structures overlapping the first electrode and the second electrode, respectively; and
a plurality of second structures between the one pair of first structures and spaced apart from each other.

3. The display device according to claim 2, wherein a cross section of the one pair of first structures is configured to have a trapezoidal structure and a cross section of the plurality of second structures is configured to have an inverted trapezoidal structure.

4. The display device according to claim 1, wherein portions of the connection layer are a continuous structure.

5. The display device according to claim 1, wherein a thickness of a first portion of the connection layer corresponding to the space between the plurality of structures is smaller than a thickness of a second portion of the connection layer which is in contact with the plurality of structures.

6. The display device according to claim 1, further comprising:
a transistor in the active area and connected to the plurality of light emitting diodes; and
a protective layer overlapping the transistor and under the transistor,
wherein the first electrode, the second electrode, and the protective layer are the same material.

7. The display device according to claim 1, wherein the plurality of light emitting diodes includes an anode, a light emitting layer, and a cathode, the display device further comprising:
a bank covering a part of the anode and disposed under the light emitting layer,
wherein at least one of the plurality of structures and the bank are the same material, and
wherein the connection layer and the cathode are the same material.

8. The display device according to claim 1, further comprising:
a transistor in the active area and connected to the plurality of light emitting diodes;
a planarization layer covering the transistor; and
anodes of the plurality of light emitting diodes on the planarization layer,
wherein at least one of the plurality of structures and the planarization layer are the same material, and
wherein the connection layer and the anodes are the same material.

9. The display device according to claim 1, further comprising:
a second substrate covering the first substrate; and
a sealing member bonding the first substrate to the second substrate,
wherein the first electrode and the second electrode protrude from an area overlapping the second substrate to outside of the second substrate and the sealing member.

10. The display device according to claim 9, wherein the connection layer is disposed inside the sealing member.

11. The display device according to claim 1, wherein whether moisture permeation occurs is detected by a resistance change of the connection layer measured by the first electrode and the second electrode.

12. The display device according to claim 1, further comprising an encapsulation structure, wherein the first electrode, the second electrode, the connection layer and the plurality of light emitting diodes are encapsulated between the encapsulation structure and the substrate.

13. The display device according to claim 12, wherein the encapsulation structure has a structure in which an inorganic layer and an organic layer are alternately laminated.

14. The display device according to claim 6, wherein the first electrode, the second electrode and the protective layer are each formed of the same material and by the same process.

15. The display device according to claim 7, wherein the plurality of structures and the bank are each formed of the same material and by the same process.

16. The display device according to claim 7, wherein the connection layer and the cathode are each formed of the same material and by the same process.
